(19) United States
(12) Patent Application Publication
(10) Pub. No.: US 2018/0061643 A1
(43) Pub. Date: Mar. 1, 2018

(54) METHOD FOR PRODUCING THIN FILM TRANSISTOR AND THIN FILM TRANSISTOR

(71) Applicant: NISSHA PRINTING CO., LTD., Kyoto-shi, Kyoto (JP)

(72) Inventors: Hideaki NADA, Kyoto-shi, Kyoto (JP); Ryomei OMOTE, Kyoto-shi, Kyoto (JP); Hirotaka SHIGENO, Kyoto-shi, Kyoto (JP); Yoshihiro SAKATA, Kyoto-shi, Kyoto (JP); Kazuto NAKAMURA, Kyoto-shi, Kyoto (JP); Hayato NAKAYA, Kyoto-shi, Kyoto (JP)

(73) Assignee: NISSHA PRITING CO., LTD., Kyoto-shi, Kyoto (JP)

(21) Appl. No.: 15/555,018

(22) PCT Filed: Mar. 2, 2016
(86) PCT No.: PCT/JP2016/056494

§ 371 Date: Aug. 31, 2017

(30) Foreign Application Priority Data
Mar. 30, 2015 (JP) 2015-070348

(51) Int. Cl. H01L 21/28; H01L 29/786; H01L 21/8238; H01L 21/3205; H01L 21/768; H01L 23/522; H01L 27/092

(52) U.S. Cl. CPC H01L 21/28; H01L 29/786; H01L 21/8238; H01L 27/092; H01L 21/768; H01L 23/522; H01L 21/3205

(57) ABSTRACT

A method for producing a thin film transistor and a thin film transistor that can suppress deterioration and variation in performance are provided. A method for producing a thin film transistor includes: forming an organic semiconductor layer on a first main surface of a substrate; forming a first conductive layer on the organic semiconductor layer, while forming a second conductive layer on a second main surface of the substrate; forming mask layers collectively on the first conductive layer and the second conductive layer; and bringing the first conductive layer and the second conductive layer collectively into contact with etching liquid so that partial regions of the first conductive layer and the second conductive layer are removed, so as to form a source electrode and a drain electrode on the organic semiconductor layer, while to form a gate electrode on the second main surface of the substrate.

### TECHNICAL FIELD

The present invention relates to a thin film transistor using an organic semiconductor as a semiconductor layer.

### BACKGROUND ART

In recent years, along with increasing needs for a thinner, more flexible and lighter transistor, a high polymer film such as polyethylene naphthalate (PEN) or polyimide (PI) is used as a substrate material. As a result, an organic semiconductor is used as a semiconductor layer, which can be formed as a film under a heat-resistant temperature thereof. In addition, a photolithography method or a printing method is used for forming a source electrode, a drain electrode, and a gate electrode constituting the thin film transistor.

Patent Citation 1 describes a thin film transistor using a gate insulating film as a substrate (base), in which electrodes and semiconductor layers are formed by the printing method.

### PRIOR ART CITATIONS

### Patent Citation

Patent Citation 1: JP-A-2006-186294

### SUMMARY OF INVENTION

### Technical Problem

In a production process of a transistor, thermal processing such as film formation or thermal treatment is repeatedly performed. For example, it is performed in vacuum film formation such as sputtering or vapor deposition, or in drying after applying process. Due to this thermal processing, the substrate may be expanded or contracted resulting in a change in dimensions of the substrate. In a production process of a transistor by the photolithography method, film formation of a layer and exposure process or the like for forming a mask layer are performed for each layer, and hence thermal treatment is performed each time when forming each layer resulting in a change in dimensions of the substrate in each step. Therefore, it is difficult to control positions for forming the source electrode and the drain electrode with respect to the gate electrode. As a result, the transistor cannot be produced as designed, and a variation occurs in performance of the transistor resulting in deterioration of production yield.

Therefore, it is an object of the present invention to provide a method for producing a thin film transistor as well as a thin film transistor, which can suppress deterioration and variation in performance.

### Technical Solution

According to one aspect of the present invention, a method for producing a thin film transistor, which can achieve the above-described object, includes:

forming a first conductive layer on a first main surface of a substrate, while forming a second conductive layer on a second main surface of the substrate;

forming mask layers collectively on the first conductive layer and the second conductive layer;

bringing the first conductive layer and the second conductive layer collectively into contact with etching liquid so that partial regions of the first conductive layer and the second conductive layer are removed, so as to form a source electrode and a drain electrode on the first main surface of the substrate, while to form a gate electrode on the second main surface of the substrate; and forming an organic semiconductor layer on the partial regions of the first conductive layer where the first conductive layer has been removed. Because the method for producing a thin film transistor according to the present invention includes the step of forming mask layers collectively on the first conductive layer and the second conductive layer, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed. In addition, in the method of producing the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film. In addition, according to a method for producing the thin film transistor of the present invention, since the source electrode, the drain electrode, and the gate electrode are formed by photolithography, the channel length can be controlled so as to be 10 μm or less, and it is possible to realize the microfabrication of the circuit.

According to a method for producing a thin film transistor of the present invention, it is preferable that the first conductive layer and the second conductive layer are made of Cu. It is because Cu has a high electric conductivity, as well as is inexpensive and superior in heat resistance.

According to a method for producing a thin film transistor of the present invention, it is preferable that the mask layer is made of a dry film resist. Compared with the case where the mask layer is formed of a liquid resist, it is not necessary to dry the solvent after applying the resist, and hence productivity can be enhanced if the mask layer is made of a dry film resist.

According to another aspect of the present invention, a thin film transistor, which can achieve the above-described object, includes:

a first transistor including
a first gate electrode formed on a first main surface of a substrate, and
a first source electrode, a first drain electrode and a first organic semiconductor layer formed on a second main surface of the substrate; and

a second transistor including
a second gate electrode formed on the second main surface of the substrate, and
a second source electrode, a second drain electrode, and a second organic semiconductor layer formed on the first main surface of the substrate.

In the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film. In the thin film transistor of the present invention, two transistors are arranged in different directions so as to sandwich the substrate, and hence an arrangement interval between neighboring transistors can be decreased so that the integration degree of the circuit can be enhanced.

It is preferable that the first gate electrode, the first source electrode, the first drain electrode, the second gate electrode, the second source electrode, and the second drain electrode are formed by collective photolithography and collective wet etching. According to the thin film transistor of the present invention, since the electrodes are formed by photolithography, the channel length can be controlled so as to be 10 μm or less and it is possible to realize the microfabrication of the circuit. In addition, because the electrodes are formed by collective photolithography and collective wet etching, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed.

It is preferable that the first source electrode or the first drain electrode and the second source electrode or the second drain electrode are arranged to overlap each other. Since an arrangement interval between neighboring transistors can be decreased so that the integration degree of the circuit can be enhanced.

It is preferable that a conductive type of the first organic semiconductor layer and a conductive type of the second organic semiconductor layer have opposite polarities, and the first transistor and the second transistor are structured in a complementary manner. In this way, the first transistor and the second transistor can be arranged to form a CMOS structure of a metal oxide semiconductor (MOS).

It is preferable that the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole. Because the first drain electrode and the second drain electrode are arranged to overlap the through holes, an arrangement interval between the transistors adjacent to each other can be reduced. In addition, because the first drain electrode and the second drain electrode are connected to each other via the through hole, the length of a wiring for connecting the first drain electrode and the second drain electrode can be shortened, and it is not necessary to secure an additional space for the wiring.

It is preferable that the substrate is made of a high polymer film, and thickness of the substrate is 0.1 μm or more to 10 μm or less. If the substrate is made of a high polymer film having a thickness of 0.1 μm or more to 10 μm or less, it is possible to maintain the number of carriers that move in the channel region per unit time, and the substrate can be easily handled.

### Advantageous Effects

In the method for producing a thin film transistor according to the present invention, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed. In addition, according to the method for producing the thin film transistor of the present invention, the channel length can be controlled so as to be 10 μm or less, and it is possible to realize the microfabrication of the circuit.

In the method of producing the transistor and the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film.

In the thin film transistor including the first transistor and the second transistor of the present invention, two transistors are arranged in different directions so as to sandwich the substrate, and hence an arrangement interval between neighboring transistors can be decreased so that the integration degree of the circuit can be enhanced.

### BRIEF DESCRIPTION OF DRAWINGS

FIG. 1 is a cross-sectional view illustrating a step of a method for producing a thin film transistor according to an embodiment of the present invention.

FIG. 2 is a cross-sectional view illustrating a step of the method for producing a thin film transistor according to an embodiment of the present invention.

FIG. 3 is a cross-sectional view illustrating a step of the method for producing a thin film transistor according to an embodiment of the present invention.

FIG. 4 is a cross-sectional view illustrating a step of the method for producing a thin film transistor according to an embodiment of the present invention.

FIG. 5 is a cross-sectional view illustrating a step of the method for producing a thin film transistor according to an embodiment of the present invention.

FIG. 6 is a cross-sectional view illustrating a step of the method for producing a thin film transistor according to an embodiment of the present invention.

FIG. 7 is a cross-sectional view illustrating another example of the thin film transistor according to an embodiment of the present invention.

FIG. 8 is a cross-sectional view illustrating another example of the thin film transistor according to an embodiment of the present invention.

FIG. 9 is a schematic diagram illustrating a structure of a CMOS circuit.

FIG. 10 is a cross-sectional view illustrating another example of the thin film transistor according to an embodiment of the present invention.

FIG. 11 is a cross-sectional view illustrating a step of the method for producing a thin film transistor according to a reference example.

FIG. 12 is a cross-sectional view illustrating a step of the method for producing a thin film transistor according to the reference example.

FIG. 13 is a cross-sectional view illustrating a step of the method for producing a thin film transistor according to the reference example.

FIG. 14 is a cross-sectional view illustrating a step of the method for producing a thin film transistor according to the reference example.

FIG. 15 is a cross-sectional view illustrating a step of the method for producing a thin film transistor according to the reference example.

FIG. 16 is a cross-sectional view illustrating a step of the method for producing a thin film transistor according to the reference example.

FIG. 17 is a cross-sectional view illustrating a step of the method for producing a thin film transistor according to the reference example.

### DESCRIPTION OF EMBODIMENTS

Hereinafter, the present invention is described in more detail based on an embodiment. The present invention is not limited to the embodiment described below but can be implemented with modifications within the spirit thereof described above and below, which are included in the technical scope of the present invention. In addition, dimensional ratios of various members illustrated in the drawings may be different from actual dimensional ratios, because priority is put on understanding of features of the present invention.

A method for producing a thin film transistor according to the present invention includes the steps of: (1) forming a first conductive layer on a first main surface of a substrate, while forming a second conductive layer on the a second main surface of the substrate; (2) forming mask layers collectively on the first conductive layer and the second conductive layer; (3) bringing the first conductive layer and the second conductive layer collectively into contact with etching liquid so that partial regions of the first conductive layer and the second conductive layer are removed, so as to form a source electrode and a drain electrode on the first main surface of the substrate, while to form a gate electrode on the second main surface of the substrate; and (4) forming an organic semiconductor layer on an area of the first main surface of the substrate where the first conductive layer has been removed. Because the method for producing a thin film transistor according to the present invention includes the step of (3) forming mask layers collectively on the first conductive layer and the second conductive layer, even if the substrate is thermally expanded or contracted, a positional relationship among the source electrode, the drain electrode, and the gate electrode can be easily maintained. As a result, performance deterioration of the transistor due to misregistration of the gate electrode with respect to the source electrode and the drain electrode can be suppressed. In the thin film transistor of the present invention, the substrate works also as a gate insulating film, and hence it is not necessary to dispose an additional gate insulating film such as a silicon oxide film. Therefore the total thickness of the transistor can be reduced. Accordingly, a variation in performance of the transistor does not occur due to a variation in quality such as pinhole occurrence or a thickness of the gate insulating film. In addition, according to a method for producing the thin film transistor of the present invention, since the source electrode, the drain electrode, and the gate electrode are formed by photolithography, the channel length can be controlled so as to be 10 μm or less, and it is possible to realize the microfabrication of the circuit.

Further, a thin film transistor of the present invention includes a substrate; a first transistor including a first gate electrode formed on a first main surface of the substrate, and a first source electrode, a first drain electrode, and a first organic semiconductor layer formed on the second surface of the substrate; and a second transistor including a second gate electrode formed on the second main surface of the substrate, and a second source electrode and a second drain electrode, and a second organic semiconductor layer formed on the first surface of the substrate. Further, in the thin film transistor of the present invention, the substrate works also as a gate insulating film, and hence it is not necessary to dispose an additional gate insulating film such as a silicon oxide film. Therefore the total thickness of the transistor can be reduced. In addition, a variation in performance of the transistor does not occur due to a variation in quality such as pinhole occurrence or a thickness of the gate insulating film. In the thin film transistor of the present invention, two transistors are arranged in different directions so as to sandwich the substrate, and hence an arrangement interval between neighboring transistors can be decreased so that the integration degree of the circuit can be enhanced.

In the present invention, the thin film transistor has thickness direction and surface direction. The thickness direction of the thin film transistor is a direction in which the organic semiconductor layer and the conductive layer are laminated on the substrate and corresponds to an up and down direction in the drawings. The surface direction of the thin film transistor is perpendicular to the thickness direction and includes a longitudinal direction and a lateral direction. Note that a left and right direction in the drawings corresponds to the lateral direction of the surface direction of the thin film transistor.

The substrate works also as the gate insulating film. The substrate is preferably made of a high polymer film such as polyethylene naphthalate (PEN), polyethylene terephthalate (PET), or polyimide (PI). Since mobility of the organic semiconductor is 1 to 10 cm²/V·sec, if the thickness of the substrate is too large, the number of carriers that move between the source electrode and the drain electrode per unit time is decreased. On the other hand, if the thickness of the substrate is too small, the substrate may be bent or broken in a production process of the transistor, and hence the substrate cannot be easily handled. From above discussion, the thickness of the substrate is preferably 0.1 μm or more to 10 μm or less, more preferably 1 μm or more to 7 μm or less, and still more preferably 3 μm or more to 5 μm or less.

The organic semiconductor layer functions as a channel region of the transistor. The material of the organic semiconductor layer is, for example, pentacene, anthracene, tetracene, rubrene, polyacethylene, polythiophene, fulleren, and carbon nanotubues.

The first conductive layer and the second conductive layer are used for forming electrodes such as a gate electrode, a source electrode, a drain electrode, a terminal electrode, a via electrode, and the like constituting the transistor. As described later in detail with an example of the production method, partial regions of the first conductive layer and the second conductive layer are covered with a mask layer, and the first conductive layer and the second conductive layer are brought into contact with etching liquid, and hence the electrodes can be formed.

For the first conductive layer and the second conductive layer, it is possible to use conductive material such as Al, Ag, C, Ni, Au, Cu, or the like, for example. Among them, it is preferred that the first conductive layer and the second conductive layer should be made of Cu. It is because Cu has a high electric conductivity, as well as is inexpensive and superior in heat resistance.

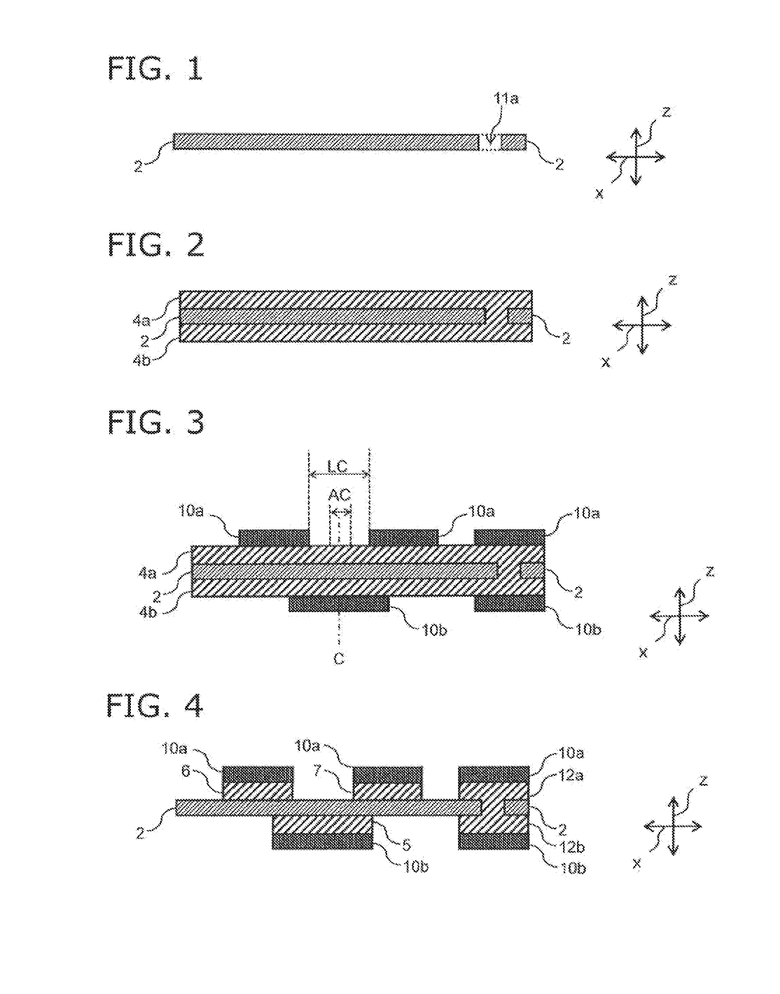

Hereinafter, a preferred example of the method for producing a thin film transistor according to this embodiment is described in detail with reference to the drawings. FIGS. 1 to 9 are cross-sectional views illustrating partial steps of the method for producing a thin film transistor according to an embodiment of this embodiment.

(1) Step of Forming the First Conductive Layer on the First Surface of the Substrate, and the Second Conductive Layer on the Second Surface of the Substrate

A polyimide film having a thickness of 3 μm is prepared as a substrate 2. In order to form the terminal electrode and the via electrode, a through hole 11a may be formed to penetrate the substrate 2 in the thickness direction z as illustrated in FIG. 1. The through hole 11a is formed by means of punching, laser processing, or the like.

As shown in FIG. 2, a first conductive layer 4a is formed on the first main surface of the substrate 2, and a second conductive layer 4b is formed on the second main surface of the substrate 2. In FIG. 2, the first conductive layer 4a is formed on the upper side of the substrate 2 in the thickness direction z, and the second conductive layer 4b is formed on the lower side of the substrate 2. The first conductive layer 4a and the second conductive layer 4b are formed by means of the vacuum vapor deposition method or the sputtering method, for example. In addition, in a case that the through hole 11a penetrating the substrate 2 in the thickness direction z are not formed, conductive material formed like a foil is attached to make the first conductive layer 4a and the second conductive layer 4b.

(2) Step of Forming the Mask Layers Collectively on the First Conductive Layer and the Second Conductive Layer

As illustrated in FIG. 3, for determining positions of the gate electrode, the source electrode, and the drain electrode, mask layers 10a and 10b are formed collectively on the first conductive layer 4a and the second conductive layer 4b, respectively.

Specifically, the mask layers 10a and 10b are formed as follows. Photosensitive resin such as dry film resist or liquid resist is applied onto the first conductive layer 4a and the second conductive layer 4b. As the photosensitive resin, there are a negative type that makes the exposed part become insoluble in the developer and a positive type that makes the exposed part become soluble in the developer. In the following description, a negative type photosensitive resin is exemplified. A first resist is applied onto the first conductive layer 4a, and a second resist is applied onto the second conductive layer 4b. The first resist and the second resist are irradiated with an electron beam or light (ultraviolet rays) so that predetermined circuit patterns are drawn on the first resist and the second resist. At least shapes of the source electrode and the drain electrode are drawn on the first resist, and at least a shape of the gate electrode is drawn on the second resist.

In order to prevent performance deterioration of the transistor, it is preferred, as illustrated in FIG. 3, that a center line C in a left and right direction x of the mask layer 10b for forming the gate electrode should be positioned in a center region AC, when the region (channel length LC) between the source electrode and the drain electrode formed by the mask layer 10a is equally divided into three parts in the left and right direction x.

The channel length LC is preferably 20 μm or less, more preferably 15 μm or less, and still more preferably 10 μm or less. As the channel length LC is shorter, operating speed of the transistor can be higher.

Using an exposure apparatus (not shown) that can collectively expose both sides of the substrate 2, both the first resist and the second resist are collectively exposed so that the circuit patterns can be transferred and burned onto the first resist and the second resist.

When the first resist and the second resist are brought into contact with the developer, unexposed parts of the resists are dissolved in the developer. As a result, exposed parts of the first resist and the second resist are left as the mask layers 10a and 10b on the first conductive layer 4a and the second conductive layer 4b.

The mask layer 10 (10a, 10b) can be formed of a dry film resist or a liquid resist, but it is preferably formed of the dry film resist. Compared with the case where the mask layer 10 is formed of a liquid resist, it is not necessary to dry the solvent after applying the resist, and hence productivity can be enhanced.

(3) Step of Bringing the First Conductive Layer and the Second Conductive Layer Collectively into Contact with the Etching Liquid so that Partial Regions of the First Conductive Layer and the Second Conductive Layer are Removed, so as to Form the Source Electrode and the Drain Electrode on the Organic Semiconductor Layer, while to Form the Gate Electrode on the Second Main Surface of Substrate.

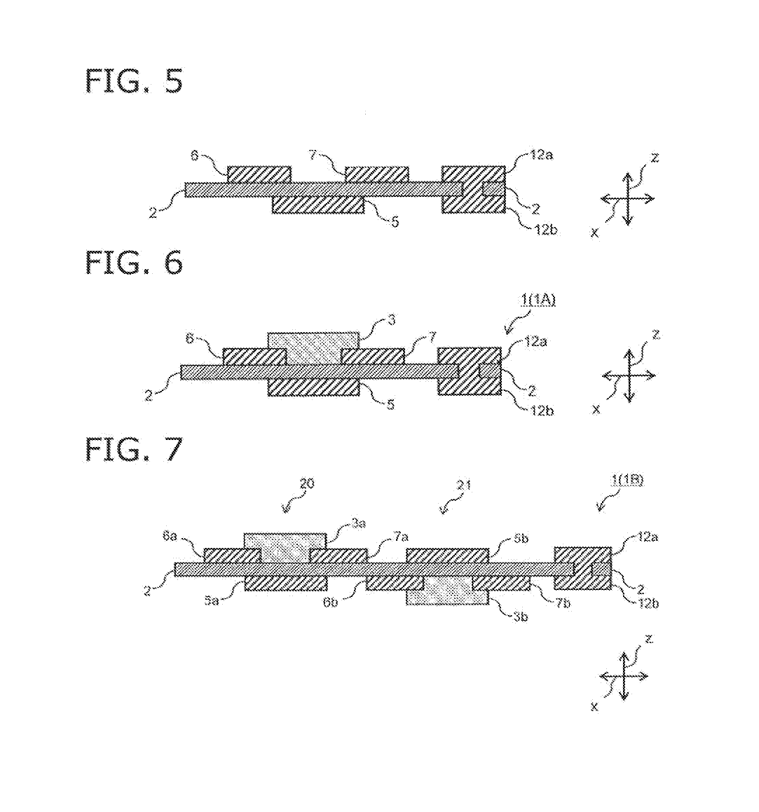

Next, the first conductive layer 4a, on which the mask layer 10a is formed, and the second conductive layer 4b, on which the mask layer 10b is formed, are collectively brought into contact with etching liquid. With this operation, partial regions of the first conductive layer 4a and the second conductive layer 4b are removed as illustrated in FIG. 4.

The mask layers 10a and 10b are brought into contact with stripping liquid to dissolve, and hence the mask layers 10a and 10b are removed. As a result, as shown in FIG. 5, a source electrode 6 and a drain electrode 7 are formed on the first main surface of the substrate 2, and a gate electrode 5 is formed on the second main surface of the substrate 2. In addition, by removing the mask layers 10a and 10b, the terminal electrode 12a are formed on the first main surface of the substrate 2, and the terminal electrode 12b are formed on the second main surface of the substrate 2. It should be noted that the terminal electrodes 12a, 12b are electrically connected with each other.

As illustrated in FIG. 5, a thin film transistor of the present invention has the source electrode 6, the drain electrode 7, and the gate electrode 5, which are formed by collective photolithography and collective wet etching. Therefore, even if the substrate 2 is thermally expanded or contracted, a positional relationship among the source electrode 6, the drain electrode 7, and the gate electrode 5 can be easily maintained. As a result, it is possible to suppress performance deterioration of the transistor due to misregistration of the gate electrode 5 with respect to the source electrode 6 and the drain electrode 7.

(4) Step of Forming an Organic Semiconductor Layer on an Area of the First Main Surface of the Substrate where the First Conductive Layer has been Removed

As shown in FIG. 6, an organic semiconductor layer 3 is formed on an area of the first main surface of the substrate 2 where the first conductive layer 4a has been removed. According to FIG. 6, the organic semiconductor layer 3 is formed on an area of the first main surface of the substrate 2 where the first conductive layer 4a has been removed, at least a part of the main surface of the source electrode 6, and at least a part of the main surface of the drain electrode 7. The method of forming the organic semiconductor layer 3 may employ deposition, inkjet, a dispenser, for example. According to the above-described operation, the thin film transistor 1 (1A) is manufactured.

Next, a thin film transistor of another implementation, which is different from the thin film transistor illustrated in FIG. 6, will be described with reference to FIGS. 7 to 10. Note that, in the description with reference to FIGS. 7 to 10, overlapping description of the same part as described above is omitted. FIGS. 7, 8, and 10 illustrate cross-sectional views in the thickness direction z of the thin film transistor.

A thin film transistor 1 (1B) of the present invention illustrated in FIG. 7 includes a substrate 2; a first transistor 20 including a first gate electrode 5a formed on the first main surface of the substrate 2, and a first source electrode 6a, a first drain electrode 7a, and a first organic semiconductor layer 3a formed on the second main surface of the substrate 2; and a second transistor 21 including a second gate electrode 5b formed on the second surface of the substrate 2, and a second source electrode 6b, a second drain electrode 7b, and a second organic semiconductor layer 3b formed on the first main surface of the substrate 2.

The first gate electrode 5a of the first transistor 20 is formed between the first source electrode 6a and the first drain electrode 7a, while the second gate electrode 5b of the second transistor 21 is formed between the second source electrode 6b and the second drain electrode 7b.

In this way, in the thin film transistor 1B of the present invention, the first transistor 20 and the second transistor 21 are arranged in different directions so as to sandwich the substrate 2, and hence an arrangement interval between neighboring transistors can be decreased so that the integration degree of the circuit can be enhanced.

It is preferred that the first gate electrode 5a, the first source electrode 6a, the first drain electrode 7a, the second gate electrode 5b, the second source electrode 6b, and the second drain electrode 7b should be formed by collective photolithography and collective wet etching. Even if the substrate 2 is thermally expanded or contracted, a positional relationship among the first gate electrode 5a, the first source electrode 6a, and the first drain electrode 7a, the second gate electrode 5b, the second source electrode 6b, and the second drain electrode 7b can be easily maintained. As a result, it is possible to suppress performance deterioration of the transistors, due to misregistration of the first gate electrode 5a with respect to the first source electrode 6a and the first drain electrode 7a, and misregistration of the second gate electrode 5b with respect to the second source electrode 6b and the second drain electrode 7b.

According to the present invention, by changing the circuit patterns drawn on the mask layer 10 by the photolithography method, a plurality of transistors can be produced in the same manner as the case where one transistor is produced, and hence productivity can be enhanced.

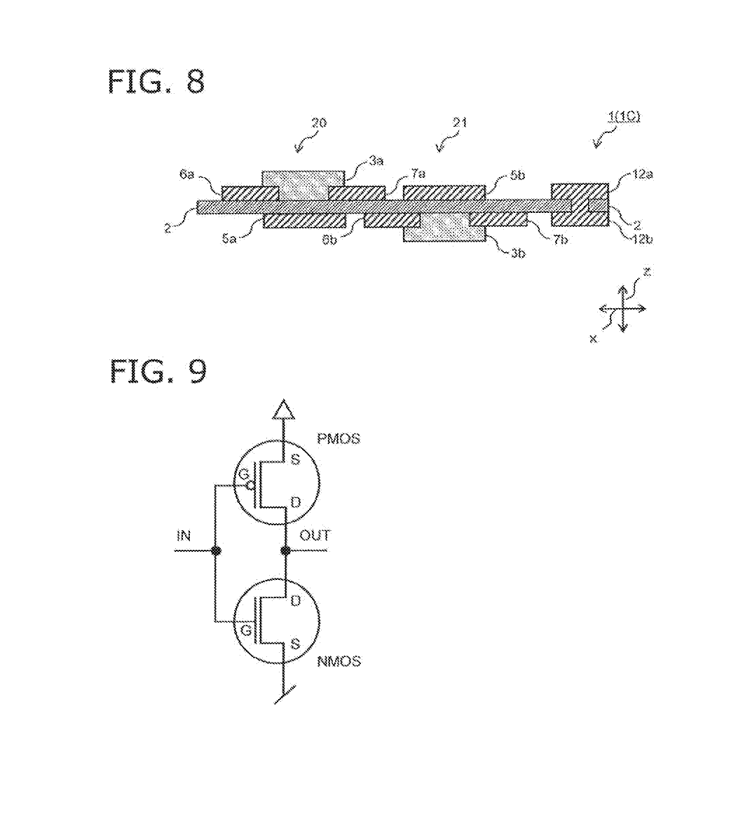

In order to further increase the integration degree of the circuit, it is preferred that the first source electrode 6a or the first drain electrode 7a and the second source electrode 6b or the second drain electrode 7b should be arranged to overlap each other. With this structure of the first transistor 20 and the second transistor 21, an arrangement interval between neighboring transistors can be further decreased. In the thin film transistor 1 (1C) illustrated in FIG. 8, the first drain electrode 7a and the second source electrode 6b are arranged to overlap each other, but in accordance with a conductive type of the semiconductor or a circuit type, the first source electrode 6a and the second source electrode 6b may be arranged to overlap each other, or the first source electrode 6a and the second drain electrode 7b may be arranged to overlap each other, or the first drain electrode 7a and the second drain electrode 7b may be arranged to overlap each other.

It is preferred that the conductive type of the first organic semiconductor layer 3a and the conductive type of the second organic semiconductor layer 3b should have opposite polarities, and that the first transistor 20 and the second transistor 21 should be complementary. In this way, the first transistor 20 and the second transistor 21 can be arranged to form a CMOS structure of a metal oxide semiconductor (MOS).

FIG. 9 is a schematic diagram illustrating a structure of a CMOS circuit. A CMOS is a circuit structure in which a pair of PMOS and NMOS is used, and operation characteristics of the PMOS and the NMOS are combined in a complementary manner, and has a feature that it can operate at low voltage so that power consumption can be reduced. In FIG. 9, G denotes the gate, S denotes the source, D denotes the drain, IN denotes the input, and OUT denotes the output.

It is sufficient if a conductive type of the first organic semiconductor layer 3a and a conductive type of the second organic semiconductor layer 3b have opposite polarities. The first organic semiconductor layer 3a may be p-type while the second organic semiconductor layer 3b may be n-type, or the first organic semiconductor layer 3a may be n-type while the second organic semiconductor layer 3b may be p-type.

The first organic semiconductor layer 3a and the second organic semiconductor layer 3b are, similarly to the above-described organic semiconductor layer, for example, pentacene, anthracene, tetracene, rubrene, polyacethylene, polythiophene, fulleren, and carbon nanotubues.

If a conductive type of the first organic semiconductor layer 3a and a conductive type of the second organic semiconductor layer 3b have opposite polarities and if the first transistor 20 and the second transistor 21 are structured in a complementary manner, the thin film transistor can be configured as follows. Specifically, as illustrated in FIG. 10, the thin film transistor 1 (1D) preferably has the structure, in which the first drain electrode 7a and the second drain electrode 7b are arranged to overlap each other, a through hole 11b is formed in the thickness direction of the substrate 2 in a region in which the first drain electrode 7a and the second drain electrode 7b overlap each other, and the first drain electrode 7a is connected to the second drain electrode 7b via the through hole 11b. Note that the through hole 11b is formed separately from the through hole 11a for connecting the terminal electrode 12a and the terminal electrode 12b. Because the first drain electrode 7a and the second drain electrode 7b are arranged to overlap each other, an arrangement interval between the first transistor 20 and the second transistor 21 in the left and right direction x in FIG. 10 can be reduced. In addition, because the first drain electrode 5a and the second drain electrode 5b are connected to each other via the through hole 11b, the length of a wiring for connecting the first drain electrode 5a and the second drain electrode 5b can be shortened, and it is not necessary to secure an additional space for the wiring. Note that, similarly to the through hole 11a for forming the terminal electrodes 12a, 12b or the via electrode, the through hole 11b can be formed by means of punching, laser processing, or the like.

### Reference Example

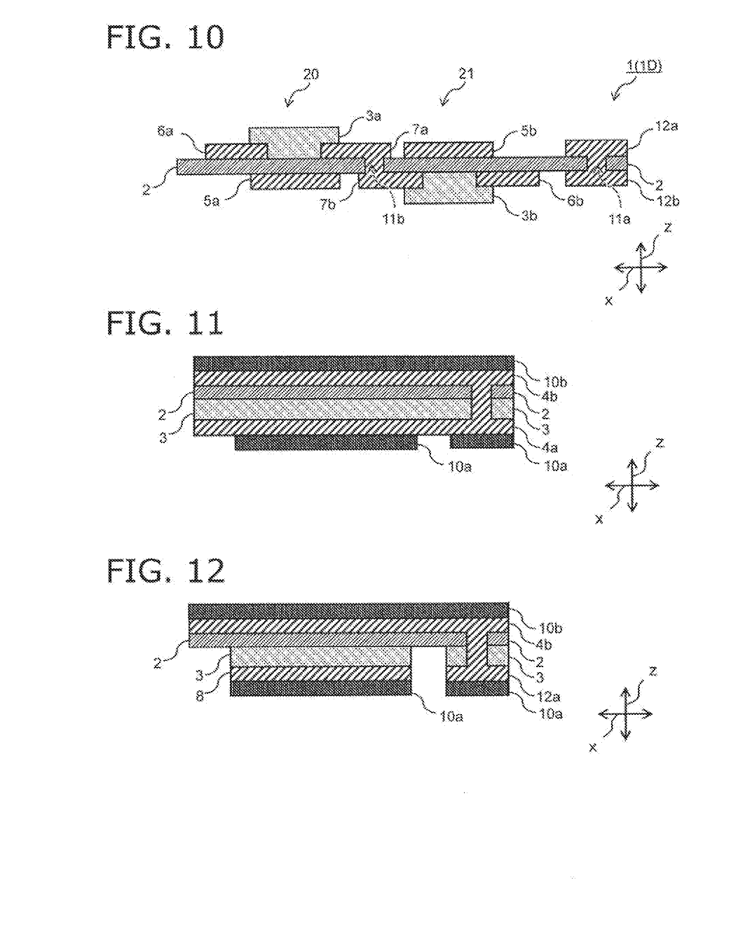

As a reference, a method for producing a thin film transistor in a case where the individual layers are formed on a first main surface of the substrate is described with reference to FIGS. 11 to 17. FIGS. 11 to 17 are a cross-sectional views illustrating steps of the method for producing a thin film transistor according to the reference example.

In FIG. 11, the organic semiconductor layer 3 is formed on the first main surface of the substrate 2, and the first conductive layer 4a is formed on the organic semiconductor layer 3. The second conductive layer 4b is formed on the second main surface of the substrate 2. The organic semiconductor layer 3 is formed by vacuum deposition. The first conductive layer 4a and the second conductive layer 4b are formed by the vacuum vapor deposition method or the sputtering method. The mask layer 10 (10a, 10B) are formed on the first conductive layer 4a and the second conductive layer 4b. The mask layer 10 is used to make electrodes, and is formed, for example, by applying and drying photoresist on the first conductive layer 4a, then transferring a circuit pattern onto the photoresist using the exposure apparatus, and finally dissolving unnecessary resist by the developer so as to remove the same. In addition, in order not to etch the second conductive layer 4b, the mask layer 10b is formed so as to cover the second conductive layer 4b entirely.

In the state where the mask layer 10a is disposed on the first conductive layer 4a, the first conductive layer 4a and the organic semiconductor layer 3 are etched by the etching liquid. In this way, as illustrated in FIG. 12, a source/drain electrode 8 (i.e., an electrode in which the source electrode and the drain electrode are connected with each other) and the terminal electrode 12a are formed.

As illustrated in FIG. 13, the mask layer 10c is formed on the source/drain electrode 8, the terminal electrode 12a, and the second main surface of the substrate 2. A circuit pattern is transferred onto the mask layer 10b (photoresist) using the exposure apparatus, and finally unnecessary resist is dissolved by the developer so as to remove the same (refer to FIG. 13).

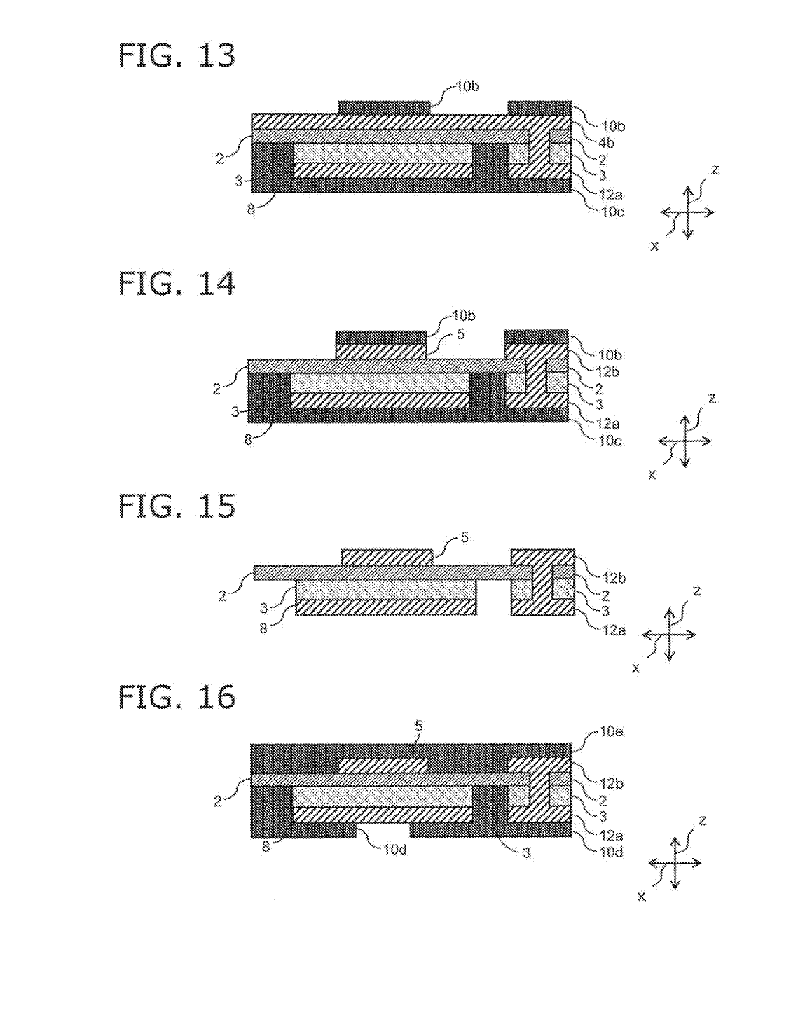

The second conductive layer 4b is etched with the etching liquid while the patterned mask layer 10 is disposed on the second conductive layer 4b. Accordingly, as shown in FIG. 14, the gate electrode 5 and the terminal electrode 12b are formed. Since the mask layer 10c is formed on the source/drain electrode 8 and the terminal electrode 12a, these electrodes are not etched.

As illustrated in FIG. 15, the mask layers 10b and 10c are brought into contact with the stripping liquid to dissolve so as to peel and remove the mask layers 10b and 10c.

As shown in FIG. 16, in order to make the source electrode and the drain electrode, the mask layer 10d is formed on the source/drain electrode 8 (i.e., on the first conductive layer 4a). At this time, the mask layer 10d is formed to cover the terminal electrode 12a so that the terminal electrode 12a will not be etched. In addition, the mask layer 10e is formed so as to cover the gate electrode 5 and the terminal electrode 12b so that the gate electrode 5 and the terminal electrode 12b will not be etched.

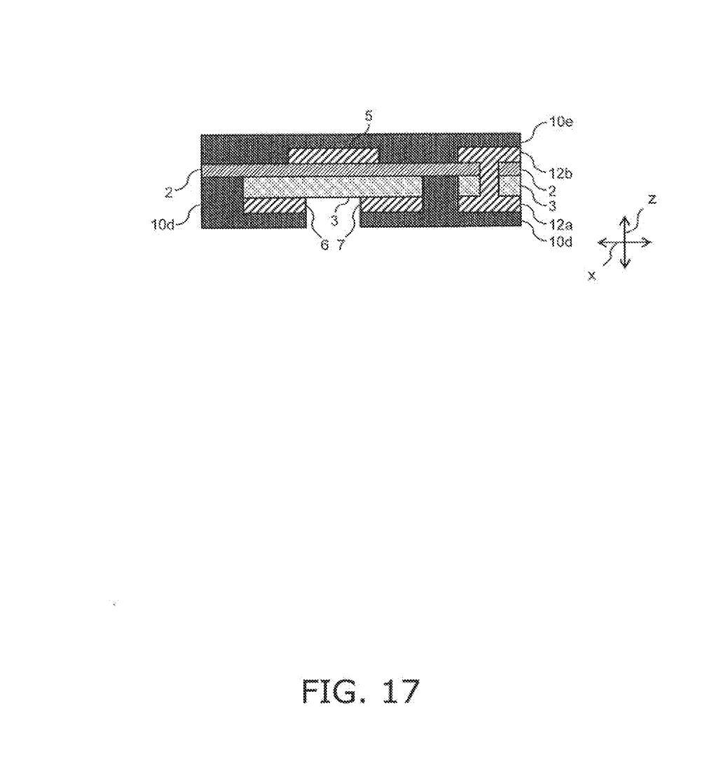

As a result of etching the source/drain electrode 8, as shown in FIG. 17, the source electrode 6 and the drain electrode 7 are formed on the organic semiconductor layer 3. Although not shown, the mask layers 10d, 10e are made into contact with stripping solution to dissolve, so that the mask layers 10d, 10e are stripped and removed so that the thin film transistor is formed.

Compared with the embodiment of the present invention, as to the laminating order and the production method of the thin film transistor according to the reference example, the exposure process and the like are performed respectively for forming the mask layer 10b for forming the gate electrode 5 and for forming the mask layer 10d for forming the source electrode 6 and the drain electrode 7. Therefore, when exposing with reference to alignment marks, deviations in registration accuracy of the apparatus are apt to be accumulated. In addition, when the substrate 2 is thermally expanded or contracted, it is difficult to control the forming positions of the source electrode 6 and the drain electrode 7 with respect to the gate electrode 5

### REFERENCE SIGNS LIST

1, 1A, 1B, 1C, 1D, 1E thin film transistor
2 substrate
3 organic semiconductor layer
3a first organic semiconductor layer
3b second organic semiconductor layer
4a first conductive layer
4b second conductive layer
5 gate electrode
5a first gate electrode
5b second gate electrode
6 source electrode
6a first source electrode
6b second source electrode
7 drain electrode
7a first drain electrode
7b second drain electrode
10, 10a, 10b, 10c mask layer
11a, 11b through hole
12a, 12b terminal electrode
20 first transistor
21 second transistor

1. A method for producing a thin film transistor, the method comprising:
forming a first conductive layer on a first main surface of the substrate, while forming a second conductive layer on a second main surface of the substrate;
forming mask layers collectively on the first conductive layer and the second conductive layer;
bringing the first conductive layer and the second conductive layer collectively into contact with etching liquid so that partial regions of the first conductive layer and the second conductive layer are removed, so as to form a source electrode and a drain electrode on the first main surface of the substrate, while to form a gate electrode on the second main surface of the substrate; and
forming an organic semiconductor layer on the partial region of the first main surface where the first conductive layer has been removed.

2. The method for producing a thin film transistor according to claim 1, wherein the first conductive layer and the second conductive layer are made of Cu.

3. The method for producing a thin film transistor according to claim 1, wherein the mask layer is made of a dry film resist.

4. A thin film transistor comprising:
a substrate;
a first transistor including a first gate electrode formed on a first surface of the substrate, as well as a first source electrode, a first drain electrode, and a first organic semiconductor layer formed on a second main surface of the substrate; and
a second transistor including a second gate electrode formed on the second main surface of the substrate, as well as a second source electrode, a second drain electrode, and a second organic semiconductor layer.

5. The thin film transistor according to claim 4, wherein the first gate electrode, the first source electrode, the first drain electrode, the second gate electrode, the second source electrode, and the second drain electrode are formed by collective photolithography and collective wet etching.

6. The thin film transistor according to claim 4, wherein the first source electrode or the first drain electrode and the second source electrode or the second drain electrode are arranged to overlap each other.

7. The thin film transistor according to claim 4, wherein a conductive type of the first organic semiconductor layer and a conductive type of the second organic semiconductor layer have opposite polarities, and the first transistor and the second transistor are structured in a complementary manner.

8. The thin film transistor according to claim 7, wherein the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole.

9. The thin film transistor according to claim 4, wherein the substrate is made of a high polymer film, and thickness of the substrate is 0.1 μm or more to 10 μm or less.

10. The method for producing a thin film transistor according to claim 2, wherein the mask layer is made of a dry film resist.

11. The thin film transistor according to claim 5, wherein the first source electrode or the first drain electrode and the second source electrode or the second drain electrode are arranged to overlap each other.

12. The thin film transistor according to claim 11, wherein a conductive type of the first organic semiconductor layer and a conductive type of the second organic semiconductor layer have opposite polarities, and the first transistor and the second transistor are structured in a complementary manner.

13. The thin film transistor according to claim 12, wherein the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole.

14. The thin film transistor according to claim 11, wherein the substrate is made of a high polymer film, and thickness of the substrate is 0.1 μm or more to 10 μm or less.

15. The thin film transistor according to claim 5, wherein a conductive type of the first organic semiconductor layer and a conductive type of the second organic semiconductor layer have opposite polarities, and the first transistor and the second transistor are structured in a complementary manner.

16. The thin film transistor according to claim 15, wherein the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole.

17. The thin film transistor according to claim 5, wherein the substrate is made of a high polymer film, and thickness of the substrate is 0.1 μm or more to 10 μm or less.

18. The thin film transistor according to claim 6, wherein a conductive type of the first organic semiconductor layer and a conductive type of the second organic semiconductor layer have opposite polarities, and the first transistor and the second transistor are structured in a complementary manner.

19. The thin film transistor according to claim 18, wherein the first drain electrode and the second drain electrode are arranged to overlap each other, a through hole is formed in the substrate in a region in which the first drain electrode and the second drain electrode overlap each other, and the first drain electrode and the second drain electrode are connected to each other via the through hole.

20. The thin film transistor according to claim 6, wherein the substrate is made of a high polymer film, and thickness of the substrate is 0.1 μm or more to 10 μm or less.
